(19) United States
(12) Patent Application Publication
(10) Pub. No.: US 2024/0297022 A1
(43) Pub. Date: Sep. 5, 2024

(54) INDPENDENT DILUTION INJECT FOR REMOTE PLASMA OXIDATION

(71) Applicant: Applied Materials, Inc., Santa Clara, CA (US)

(72) Inventors: Hansel LO, San Jose, CA (US); Erika HANSEN, San Jose, CA (US); Christopher S. OLSEN, Fremont, CA (US)

(21) Appl. No.: 18/364,233

(22) Filed: Aug. 2, 2023

Related U.S. Application Data
(60) Provisional application No. 63/449,832, filed on Mar. 3, 2023.

(51) Int. Cl. H01J 37/32; C04B 35/584; C04B 41/45; C04B 41/50; C04B 41/87

(52) U.S. Cl. CPC H01J 37/32449; C04B 35/584; C04B 41/4533; C04B 41/4556; C04B 41/5035; C04B 41/87; H01J 37/32357; H01J 37/32926; H01J 2237/338

(57) ABSTRACT

The disclosure provides system, computer readable medium, and method for producing a hydroxyl radical. A plasma of a plasma gas is formed, via a controller, using a remote plasma source fluidly coupled to a gas inlet conduit coupled to a first nozzle of a processing chamber. A first gas radical is produced by flowing a first gas from a first gas source through the remote plasma source. The first gas radical is introduced into the processing chamber using the gas inlet conduit coupled to the first nozzle. A second gas from a second gas source is introduced using a plurality of second nozzles fluidly of the processing chamber. An oxidation radical is produced by mixing the first gas radical and the second gas in the processing chamber.

### CROSS-REFERENCE TO RELATED APPLICATIONS

This application claims benefit of U.S. Provisional Patent Application No. 63/449,832, filed Mar. 3, 2023, the entirety of which is herein incorporated by reference.

### BACKGROUND

### Field

Embodiments of the present disclosure generally relate to a process chamber for processing a substrate, and related methods.

### Description of the Related Art

Remote plasma sources are commonly used to provide activated gases comprising radical and/or ion species to a processing volume of a process chamber, and to a surface of a substrate disposed in the processing volume, during the manufacturing of electronic devices, such as semiconductor devices on the substrate. In one such process, a processing gas is provided to the remote plasma source, a plasma is formed from the processing gas in the remote plasma source, and the plasma is flowed into the processing volume of the process chamber where a surface of a substrate is exposed thereto. Unfortunately, conventional remote plasma sources are generally incompatible with plasmas formed from certain chemistries, including high concentrations of hydrogen, such as concentrations more than 20 atomic percent (at %), because higher concentrations of hydrogen ions in the plasma may result in damage to the dielectric surfaces of the remote plasma source.

Conventional approaches to overcome this dielectric include producing atomic hydrogen using a hot-wire source where molecular hydrogen is thermally dissociated into radical (atomic) species through collision with a hot-wire filament, for example, a tungsten filament. However, hot-wire dissociation of hydrogen can lead to undesirable metal contamination on the surface of the substrate, such as tungsten contamination, from the hot-wire filament.

Accordingly, improved methods of and apparatuses for oxidation processes are needed.

### SUMMARY

In an aspect, the disclosure provides a processing system, having a processing chamber. The system includes a gas inlet conduit coupled to a first nozzle of the processing chamber. The system includes a remote plasma source fluidly coupled to the gas inlet conduit. The remote plasma source is fluidly coupled to a first gas source. The system includes a second gas source fluidly coupled to a plurality of second nozzles of the processing chamber. The first nozzle of the process substrate is oriented on a first side of the processing chamber and the plurality of the second nozzles are oriented on a second side of the processing chamber. The processing chamber includes a controller configured to form a plasma of a plasma gas using the remote plasma source, produce a first gas radical by flowing the first gas through the remote plasma source, introduce the first gas radical into the processing chamber using the first nozzle, introduce a second gas using the plurality of second nozzles fluidly coupled to the second gas source, and produce an oxidation radical by mixing the first gas radical and the second gas in the processing chamber

In another aspect, the disclosure provides a method of producing hydroxyl radicals. The method includes forming, via a controller, a plasma of a plasma gas using a remote plasma source fluidly coupled to a gas inlet conduit coupled to a first nozzle of a processing chamber. A first gas radical is produced by flowing a first gas from a first gas source through the remote plasma source. The first gas radical is introduced into the processing chamber using the gas inlet conduit coupled to the first nozzle. A second gas from a second gas source is introduced using a plurality of second nozzles fluidly of the processing chamber, in which the first nozzle of the process substrate is oriented on a first side of the processing chamber and the plurality of second nozzles are oriented on a second side of the processing chamber. An oxidation radical is produced by mixing the first gas radical and the second gas in the processing chamber.

In another aspect, the disclosure provides a computer readable medium. The computer readable medium is configured to form a plasma of a plasma gas using a remote plasma source fluidly coupled to a gas inlet conduit coupled to a first nozzle of a processing chamber. A first gas radical is produced by flowing a first gas from a first gas source through the remote plasma source. The first gas radical is introduced into the processing chamber using the gas inlet conduit coupled to the first nozzle. A second gas from a second gas source is introduced using a plurality of second nozzles fluidly of the processing chamber, in which the first nozzle of the process substrate is oriented on a first side of the processing chamber and the plurality of second nozzles are oriented on a second side of the processing chamber. An oxidation radical is produced by mixing the first gas radical and the second gas in the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A is a schematic cross-sectional view of a process chamber, according to embodiments of the present disclosure.

FIG. 1B is a schematic cross-sectional view of a gas injection assembly shown, according to embodiments of the present disclosure.

FIG. 1C is a schematic cross-sectional view of an orifice of a gas injection assembly, according to embodiments of the present disclosure.

FIG. 2 is a schematic cross-sectional view of a portion of a gas injection assembly, according to embodiments of the present disclosure.

FIG. 3 is a schematic cross-sectional view of a portion of a gas injection assembly, according to embodiments of the present disclosure.

FIG. 4 is a schematic perspective view of an embodiment of a gas injection assembly that may be used in conjunction with or instead of the gas injection assembly in FIG. 1.

FIGS. 5A and 5B are schematic perspective views of a processing chamber having a first nozzle and a plurality of second nozzles, according to embodiments of the disclosure. FIG. 5A is a schematic perspective view of a first nozzle oriented on a first side and a plurality of second nozzles on a second side. FIG. 5B is a schematic perspective view of a first nozzle oriented on a first side and a plurality of second nozzles on a third side.

FIG. 6 is a diagrammatic representation of a method of remote plasma oxidation, according to embodiments of the disclosure.

FIGS. 7A-7C depicts diagrammatic representation of memory hole of a substrate, according to embodiments of the disclosure. FIG. 7A depicts a memory hole before oxidation. FIG. 7B depicts a memory hole during hydroxyl radical flow. FIG. 7C depicts a memory hole after hydroxyl radical combustion oxidation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure provides a system for providing a high-pressure oxidation process while maintaining conformality, throughput, and oxide quality. In certain aspects, the system may allow for tuning conformality without requiring adjustments to the temperature of the processing chamber. Additionally, the present disclosure provides for a remote plasma system with reduced H⁺ damage to dielectric liners of the remote plasma system.

In certain aspects, the system is capable of performing high-pressure oxidation reactions because of the plurality of orifices or nozzles that promote fuel and oxidation combustion reactions. The orifices or nozzles may inject one or more radical reactive gases, such as hydrogen gas, oxygen gas, or an inert gas that have been formed using a remote plasma source. The orifices or nozzles may provide a cross-flow (or intersecting flow) of combustion reactants, e.g., radical O₂ and molecular H₂, such that mixing of the reactants occurs and promotes a uniform oxidation reaction on a substrate in the processing chamber.

### Processing Chamber

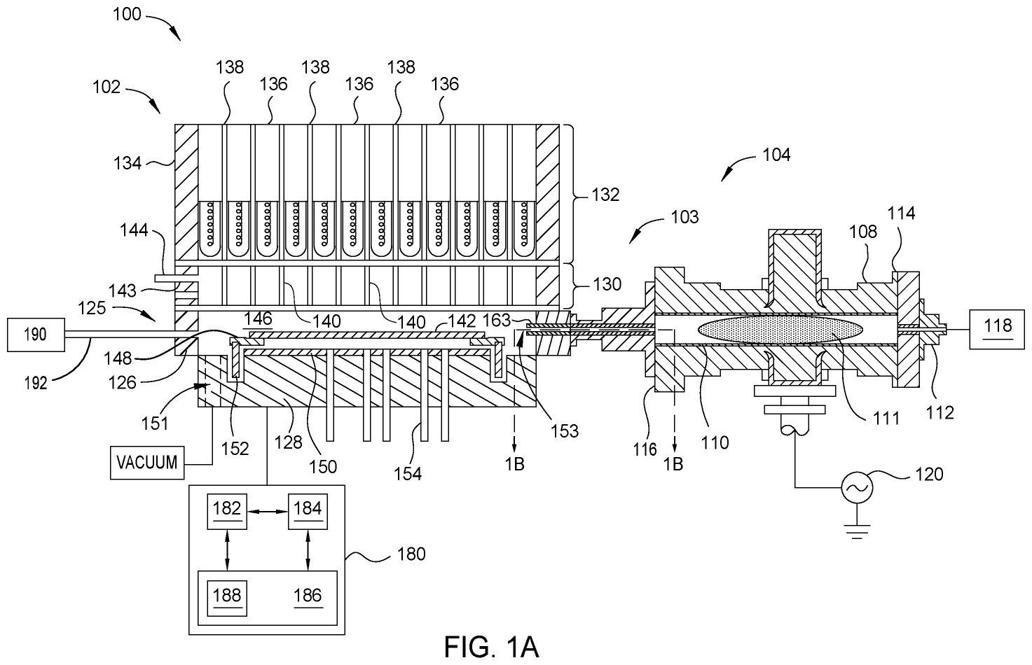

FIG. 1A is a schematic cross-sectional view of a processing chamber, according to one embodiment. The processing chamber 100 includes a process chamber 102, a remote plasma source (RPS) 104, a gas injection assembly 103 coupling the RPS 104 to the process chamber 102, and a second gas source 190 fluidly coupled to the process chamber 102 by a carrier conduit 192. Herein, the process chamber 102 is a rapid thermal processing (RTP) chamber, such as a rapid thermal anneal (RTA) chamber. The process chamber 102 may be any other process chamber where delivery of at least metastable radical molecular species and/or radical atomic species to a processing volume is desired. For example, and without limitation, the process chamber may alternatively be plasma enhanced or plasma assisted deposition chamber, such as a plasma-enhanced chemical vapor deposition (PECVD) chamber or a plasma-enhanced atomic layer deposition chamber (PEALD).

A controller 180 coupled to the processing chamber 100 is used to control the operation of the process chamber 102, the RPS 104, and the gas flow from the gas injection assembly 103, and the second gas source 190. The controller 180 generally includes a central processing unit (CPU) 182, a memory 186, and support circuits 184 for the CPU 182. The controller 180 may control the processing chamber 100 directly, or via other computers and/or controllers (not shown) coupled to the process chamber 102, the RPS 104, the gas injection assembly 103, and/or the second gas source 190, such that a rate of gas flow from the RPS 104 and/or a second gas source 190 is controlled as the gas flow from the RPS 104 and/or a second gas source 190 enters the process chamber 102.

The controller 180 described herein is any form of a general-purpose computer processor that is used in an industrial setting for controlling various chambers and sub-processors thereon or therein. The memory 186, or computer-readable medium, is one or more of readily available memory such as random access memory (RAM), read only memory (ROM), floppy disk, hard disk, flash drive, or any other form of digital storage, local or remote. The support circuits 184 are coupled to the CPU 182 for supporting the processor in a conventional manner. The support circuits 184 include cache, power supplies, clock circuits, input/output circuitry and subsystems, and the like. In one example, substrate processing parameters are stored in the memory 186 as a software routine 188 that is executed or invoked to turn the controller 180 into a specific purpose controller to control the operations of the processing chamber 100. The controller 180 is configured to perform any of the methods described herein.

The process chamber 102 includes a chamber base 125, a lamp assembly 132, and a window assembly 130 coupled to the lamp assembly 132. The chamber base 125 includes a base wall 128 and one or more first sidewalls 126. The base wall 128, the one or more first sidewalls 126, and the window assembly 130 define a processing volume 146. The window assembly 130 is disposed between the processing volume 146 and the lamp assembly 132. Herein, the lamp assembly 132, enclosed by one or more second sidewalls 134, includes a plurality of lamps 136 each disposed in a respective tube 138. The window assembly 130 includes a plurality of light pipes 140, where each of the plurality of light pipes 140 is aligned with a respective tube 138 of the lamp assembly 132 so that the radiant thermal energy provided by the plurality of lamps 136 is directed to a substrate 142 disposed in the processing volume 146.

One or more respective volumes in the plurality of light pipes 140 are maintained at sub-atmospheric conditions using one or more vacuum exhaust pumps (not shown) in fluid communication therewith through an opening 144 formed in one of the one or more second sidewalls 134. The window assembly 130 further includes a conduit 143 disposed therein for circulating a cooling fluid from a cooling fluid source (not shown) between the plurality of light pipes 140. Herein, the processing volume 146 is fluidly coupled (connected) to a chamber exhaust, such as to one or more dedicated vacuum pumps, through one or more exhaust ports 151. The chamber exhaust maintains the processing volume 146 at sub-atmospheric conditions and evacuates processing and other gases therefrom.

### Substrate Support

A support ring 148 disposed in the processing volume 146 is used to support a substrate 142 during the processing thereof. The support ring 148 is coupled to a rotatable cylinder 152 which is used to rotate the support ring 148 about a vertical axis thereof to facilitate uniform heating of the substrate 142. The rotatable cylinder 152 may be levitated and rotated by a magnetic levitation system. A reflector plate 150 disposed on the base wall 128 in the processing volume 146 is used to reflect energy to a non-device surface of the substrate 142 to further facilitate uniform heating of the substrate 142. One or more temperature sensors, such as pyrometers 154 disposed through the base wall 128 and further disposed through the reflector plate 150, are used to monitor the temperature of the substrate 142 during the processing thereof. An activated gas, formed according to embodiments described herein, flows into the processing volume 146 of the process chamber 102 through an inlet port 153, disposed through one of the one or more first sidewalls 126, which is fluidly coupled to the gas injection assembly 103. The inlet port 153 is defined by a first nozzle, such as first nozzle 163, however other arrangements are contemplated. Herein, the activated gas comprises molecular and/or atomic species, at least metastable radical molecular and/or radical atomic species, or combinations thereof. The inlet port 153 may be positioned along a first side of the processing chamber.

### Plasma

The RPS 104 herein is coupled to a power supply 120, such as a microwave or RF power supply, which is used to ignite a plasma 111 therein. The RPS 104 may use an inductively coupled plasma (ICP) source, a transformer coupled plasma (TCP source), or a capacitively coupled plasma (CCP source). The RPS 104 includes an RPS body 108 disposed about a tube 110 in which the plasma 111 is formed. The tube 110 is formed of a dielectric material, such as silicon oxide, aluminum oxide, or combinations thereof. The RPS body 108 includes a first end 114 coupled to an inlet 112 which is in fluid communication with one or more first gas sources 118 and a second end 116, distal from the first end 114, coupled to the gas injection assembly 103. An example gas injection assembly is further described in FIG. 1B.

### Gas Injection Assembly

FIG. 1B is a schematic sectional view of a portion of the gas injection assembly 103 taken along line 1B-1B of FIG. 1A. Herein, the gas injection assembly 103 includes a body 170 formed of a metal, such as stainless steel, a low recombination dielectric liner 173, such as quartz or sapphire, and a first flange 171 to couple the gas injection assembly 103 to one of the one or more sidewalls of a process chamber. The gas injection assembly 103 is coupled to a sidewall such as the one of the one or more first sidewalls 126 of the process chamber 102 described in FIG. 1A. The gas injection assembly further includes a second flange 172 to couple the gas injection assembly 103 to an RPS, such as the RPS 104 described in FIG. 1A, and optionally one or more gas injection ports 174 formed through the body 170 and the liner 173. The gas injection assembly 103 has a length L(1), measured along its longitudinal axis A between a mounting surface plane of the first flange 171 and a mounting surface plane of the second flange 172, where the length L(1) is between about 25 mm and about 150 mm, such as between about 50 mm and about 100 mm, such as between about 75 mm and about 100 mm. However, other dimensions are contemplated.

A plasma 111 formed in the RPS 104 flows into the gas injection assembly 103 where radicals and/or ions, for example oxygen ions, from the plasma collide with the molecular species of one or more second gases, for example H₂, injected into the internal volume through the carrier conduit 192 (shown in FIG. 1A). The radicals and/or ions provided by the plasma 111 have sufficient energy to dissociate the molecular species, through collision therewith, into an activated gas comprising at least metastable radical molecular species and/or radical atomic species, for example atomic hydrogen. In doing so, a relatively higher concentration of radical atomic hydrogen (e.g., greater than 20 atomic percent) can be achieved in the processing volume while avoiding damage to the dielectric components of the gas injection assembly 103. In particular, radical atomic hydrogen concentrations through the gas injection assembly can be limited to concentrations (e.g., less than 20 atomic percent) with minimal or acceptable levels of damage while still producing process benefits facilitated by higher levels (e.g., greater than 20 atomic percent) of radical atomic hydrogen. Without being bound by theory, higher levels of radical atomic hydrogen allows for controlled deposition rate and/or growth rate while processing at higher temperatures, enabling improved conformality without sacrificing oxide quality, relative to conventional processes.

Each of the one or more gas injection ports 174 comprise an opening formed through the body 170 and further through the liner 173. A diameter D(2) of the one or more gas injection ports 174 is between about 0.5 mm and about 6 mm, such as between about 1 mm and about 6 mm, such as between about 2 mm and about 5 mm, for example between about 2 mm and about 4 mm. However, other dimensions are also contemplated. In some examples, the one or more gas injection ports 174 are located at a distance L(2), as measured along the longitudinal axis A from a mounting surface plane of the first flange 171 to one or more longitudinal axis E of the one or more respective gas injection ports 174. The distance L(2) is between about 20 mm and about 80 mm, such as between about 30 mm and about 60 mm, or less than about 80 mm, such as less than about 60 mm. A longitudinal axis E of the one or more gas injection ports forms an angle with the longitudinal axis A of the gas injection ports where the angle ϕ is substantially 90°. The angle ϕ is less than about 90° so that the second gas as introduced through the gas injection port 174 is generally flowing in the downstream direction towards the inlet port 153 of the process chamber 102 and not upstream towards the RPS 104. In one example, molecular hydrogen is introduced through the inject ports 174. In such an example, the total concentration of hydrogen within the gas injection assembly 103 may be maintained below 20 atomic percent to reduce damage to the liner 173.

In one example, a longitudinal axis A of the gas injection assembly 103 intersects with a longitudinal axis B of the inlet port 153 (disposed through one of the one or more sidewalls 126 of a process chamber 102) at an angle θ of between about 0° (i.e., co-linear) and about 80°, such as between about 10° and about 70°, such as between about 20° and about 70°, or between about 10° and about 45°, for example between about 20° and about 45°. The longitudinal axis A of the gas injection assembly 103 and a longitudinal axis C of the RPS 104 form an angle α of less than about 45°, such as less than about 30°, such as less than about 20°, for example less than about 10°, or between about 0° and or about 20°, for example between about 10° and about 20°. The longitudinal axis C of the RPS 104 and the longitudinal axis A of the gas injection assembly 103 are substantially co-linear or are substantially parallel. Providing an angle θ, and/or an angle α of more than about 0° promotes recombination of ions with electrons or other charged particles through collision therebetween as the ions lose momentum through collisions when hitting the interior surfaces of the inlet port 153.

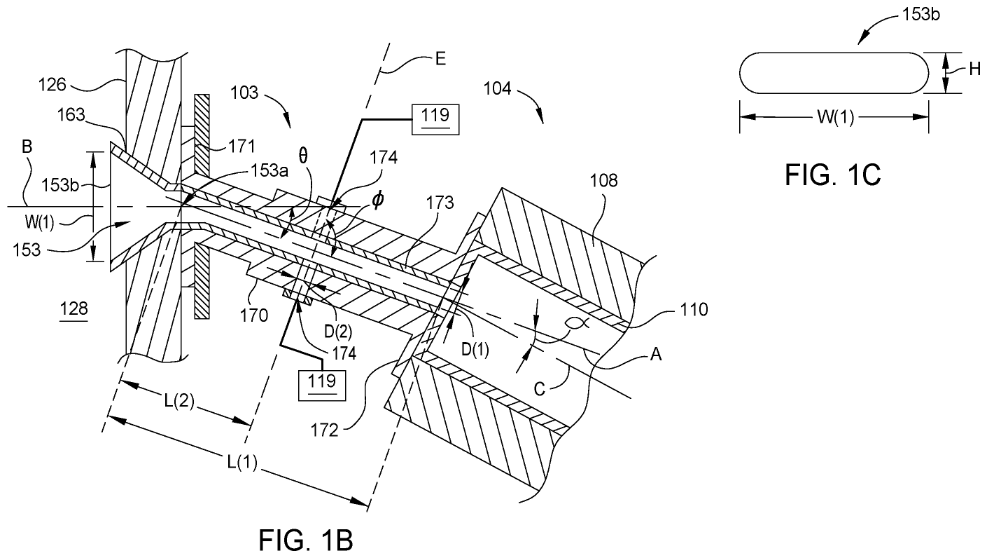

FIG. 2 is a schematic cross-sectional view of a portion of a gas injection assembly 203, according to another embodiment. The gas injection assembly 203 is substantially similar to the gas injection assembly 103 described in FIGS. 1A-1C except that one or more gas injection ports 274 disposed through the body 170 and the liner 173 have a substantially slit (e.g., elongated) cross-sectional shape at a first opening 274a in the liner 173 and a substantially circular cross-sectional shape at a second opening 274b in a surface of the body 170. Herein, the one or more first openings 274a have a length L(3) to width W(2) ratio, of more than 1:1, such as more than 2:1, for example more than about 3:1. The width W(2) may be between about 0.5 mm and about 6 mm, such as between about 1 mm and about 5 mm, for example between about 1 mm and about 4 mm. The one or more first openings 274a of the one or more gas injection ports 274 are substantially parallel, along a length L(3), to the longitudinal axis A of the gas injection assembly 203. The one or more first openings 274a of the one or more gas injection ports 274 may be substantially orthogonal to the longitudinal axis A along a length L(3). The first openings 274a of the one or more gas injection ports 274 may be of any other orientation to the longitudinal axis A. The cross-sectional shape of the gas injection port 274 gradually changes from a substantially circular cross-sectional shape (orthogonal to the longitudinal axis E) at the second opening 274b to the substantially slit cross-sectional shape at the first opening 274a to direct gas flow therethrough to ribbon like flow. The one or more gas injection ports 274 may maintain a substantially slit cross-sectional shape from the second opening 274b to the first opening 274a and substantially the same cross-sectional opening area therethrough.

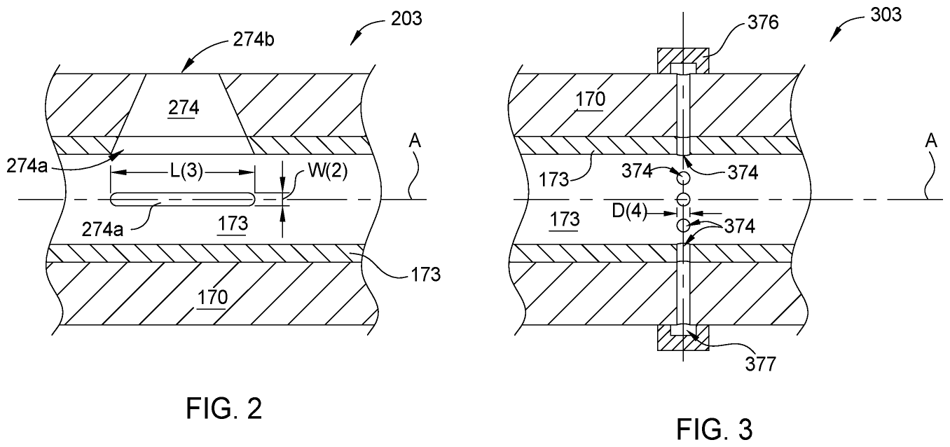

FIG. 3 is a schematic cross-sectional view of a portion of a gas injection assembly 303, according to another embodiment. The gas injection assembly 303 is substantially similar to the gas injection assembly 103 described in FIGS. 1A-1C except that processing gases are delivered through a plurality of openings 374 formed through the liner 173 and the body 170, where the plurality of openings 374 are in fluid communication with an annular passage 377 disposed in an annular ring 376 coupled to the body 170 and concentrically disposed about a circumference thereof. Each of the plurality of openings 374 have a diameter D(4) between about 0.1 mm and about 5 mm, such as between about 0.5 mm and about 4 mm, or between about 0.5 mm and about 4 mm, for example between about 1 mm and about 4 mm.

### Second Gas Source

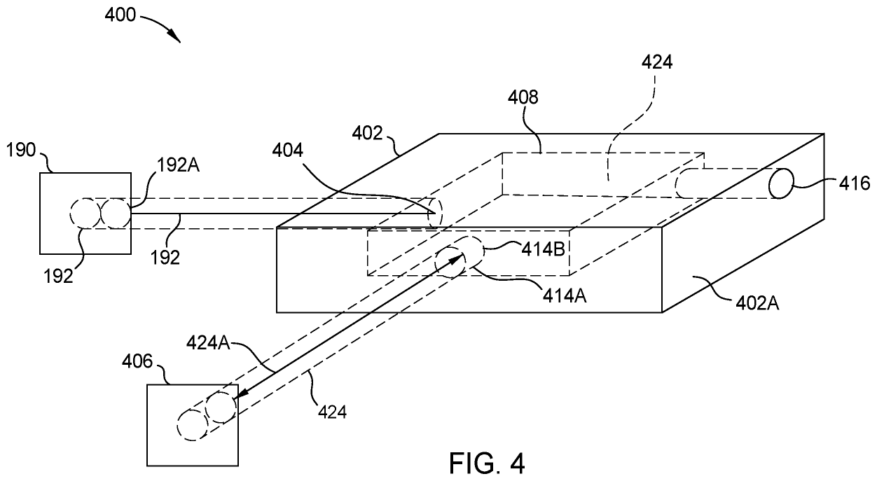

FIG. 4 is a schematic perspective view of a substrate processing chamber 400 comprising a chamber body 402 that is fluidly coupled (connected) to a remote plasma system (RPS) 406 and a second gas source 190. The second gas source 190 may be used in addition to, or in place of, gas provided through of any of gas injection portions, 174, 274, or 374. By providing process gas, such as hydrogen, from the second gas source 190, ionization of hydrogen within plasma conduits 424 is reduced, resulting in less damage to the plasma conduit 424. For clarity, the plasma conduit 424 is similar to, or may be used in place of, the gas injection assembly 103 shown in FIG. 1A.

The processing chamber 400 is similar to the processing chamber 100. A main gas inlet conduit 414A coupled to a gas inlet 414B and a gas outlet 416 are also illustrated. The RPS 406 delivers plasma to the internal volume 408 via the main gas inlet conduit 414A and a gas inlet 414B of the internal volume 408 via a plasma conduit 424. The second gas source 190 delivers a second gas to the internal volume 408 via a carrier conduit 192. The second gas source 190 may include a second gas of O₂ and/or H₂. The carrier conduit 192 extends from an outlet 192A of the second gas source 190 to the internal volume 408. A gas or gas mixture from the second gas source 190 passes to the internal volume 408 via the carrier conduit 192. While the carrier conduit 192 is positioned approximately 90 degrees from the plasma conduit 424, other configurations are also contemplated. For example, the carrier conduit 192 may be positioned approximately 180 degrees from the plasma conduit 424.

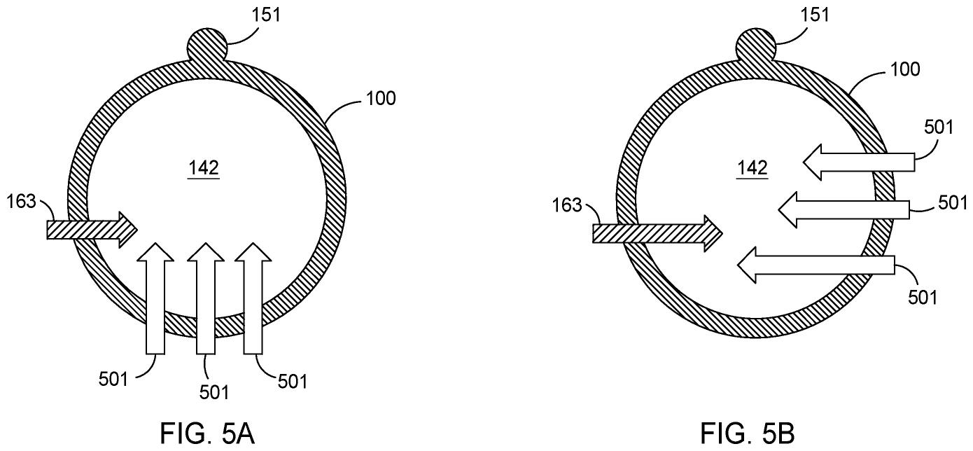

The carrier conduit 192 extends to the internal volume 408 and injects one or more second gasses using a plurality of second nozzles 501, as shown in FIGS. 5A and 5B. The plurality of second nozzles 501 inject gases approximately 90 degrees or 180 degrees relative to the gas flow from the first nozzle 163. The non-parallel gas inject of nozzles 163 and 501 improves mixing and/or reaction of gases. For example, the non-parallel flow of molecular species (e.g. hydrogen and optionally oxygen) from the nozzles 501 relative to the flow of ionized and/or radicalized species from nozzle 163 results in relatively greater ionization/radicalization of species of the gas provided through the nozzles 501. While examples illustrate 90 and 180 degree intersecting flows, it is to be noted that other angles are also contemplated. Moreover, it is to be noted that the specific number of nozzles 163, 501 as illustrated are not intended to be limiting, and other amounts of nozzles are contemplated.

The plurality of second nozzles 501 may range from about 1 to about 15 orifices, e.g., about 3 orifices to about 8 orifices, such as about 1 orifice, about 2 orifices, about 3 orifices, about 4 orifices, about 5 orifices, about 6 orifices, about 7 orifices, about 8 orifices, about 9 orifices, about 11 orifices, about 12 orifices, about 13 orifices, about 14 orifices, about 15 orifices, or the like. The process chamber may include a main gas inlet conduit 414A and a plurality of second nozzles, e.g., about 1 to about 10, such as about 3, as shown in FIGS. 5A and 5B.

### Substrate Memory Hole

The first gas radical and the second gas source mix in the internal volume of the processing chamber to oxidize a substrate or a portion of the substrate. Without being bound by theory, higher levels of radical atomic hydrogen allows for controlled deposition rate and/or growth rate while processing at higher temperatures, enabling improved conformality without sacrificing oxide quality, relative to conventional processes. A substrate may include a plurality of memory holes. A “memory hole,” as used herein, refers to a vertical channel extending two or more physical levels of the substrate. The memory holes may include a vertical trench that is formed to divide one or more memory hole structures into two or more vertical “NOT AND” (NAND) strings. A memory hole may include a vertical channel extending 32 layers, 64 layers, 96 layers, or 112 layers of a substrate.

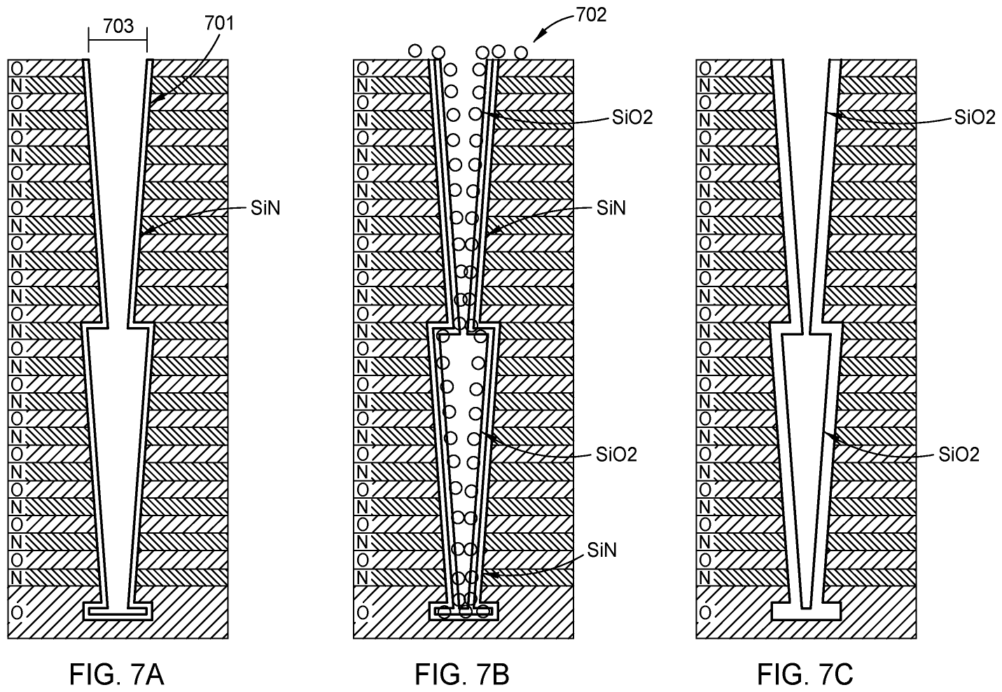

The plurality of memory holes have a substantially vertical and uniform vertical trench. The plurality of memory holes may comprise one or more vertical features, e.g., necking, clogging, bowing, striations, tapered profiles, underlayer recesses, distortions, tiltings, twistings, or the like. The plurality of memory holes has a first vertical trench comprising a tapered profile extending 16 layers, in which a second vertical trench comprising a tapered profile extends beyond the first vertical trench, creating a shelf, as shown in FIG. 7A.

The plurality of memory holes includes an outer layer 701 within the vertical trench. The outer layer 701 may include a layer of one or more silica substrates, e.g., silicon nitride, silicon dioxide, or the like. For example, and without limitation, the outer layer 701 is a silicon nitride layer. As a further non-limiting example, the outer layer 701 is a silicon dioxide layer.

### Oxidation Process

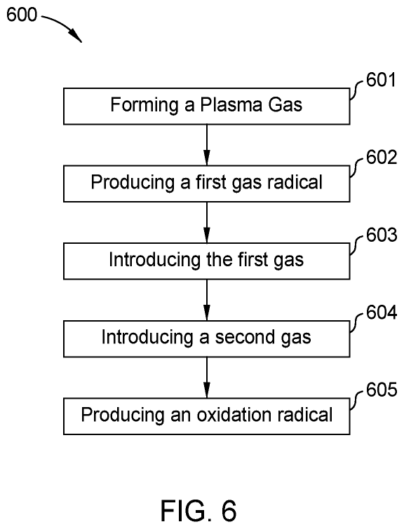

Now referring to FIG. 6, a method 600 of remote plasma oxidation, at operation 601, the method includes forming a plasma of a plasma gas using a remote plasma source. Herein, the plasma gas comprises one or more noble gases, such as argon, helium, neon, xenon, krypton, or a combination thereof. For example, and without limitation, the plasma gas is argon. At operation 602, a first gas radical is produced by flowing a first gas such as a reactive gas mixture e.g., argon, hydrogen, oxygen or any combination thereof, through the plasma remote source to produce radicals of the first gas via interaction with a plasma. At operation 603 the radicals are introduced, via a plasma conduit, into a processing chamber. The processing chamber has a substrate disposed therein.

The first gas radicals are introduced to the processing chamber 100 using a first nozzle 163. The first nozzle 163 may introduce the first gas radicals towards the substrate at a volumetric flow rate of about 5 slm to about 40 slm, e.g., about 5 slm, about 6, slm, about 7 sim, about 8 slm, about 9 sim, about 10 slm, about 11 slm, about 12 slm, about 13 slm, about 14 slm, about 15 slm, about 16 slm, about 17 slm, about 18 slm, about 19 slm, about 20 slm, about 21 slm, about 22 slm, about 23 slm, about 24 slm, about 25 slm, about 26 slm, about 27 slm, about 28 slm, about 29 slm, about 30 slm, about 31 slm, about 32 sim, about 33 slm, about 34 sim, about 35 slm, about 36 slm, about 37 slm, about 38 slm, about 39 slm, about 40 slm or the like.

The first gas radicals may be introduced from the first nozzle 163 towards the substrate at a gas velocity of about 1 m/s to about 20 m/s, e.g., about 1 m/s, about 2 m/s, about 3 m/s, about 4 m/s, about 5 m/s, about 6 m/s, about 7 m/s, about 8 m/s, about 9 m/s, about 10 m/s, about 11 m/s, about 12 m/s, about 13 m/s, about 14 m/s, about 15 m/s, about 16 m/s, about 17 m/s, about 18 m/s, about 19 m/s, about 20 m/s, or the like. The first gas radicals may be introduced from the first nozzle 163 towards the substrate with enough gas velocity to spread the gases over the substrate.

At operation 604, the method 600 includes introducing a second gas, via controller second gas conduit, into the processing chamber 100 using a plurality of second nozzles 501. The second gas may include a reactive gas, e.g., H₂, O₂, or the like, or an inert gas, e.g., N₂, He, Ar, or the like, or a combination thereof.

The second gas is introduced from the plurality of second nozzles 501, as instructed by the controller. The plurality of second nozzles 501 may introduce the second gas towards the substrate at a volumetric flow rate of about 5 slm to about 40 slm, e.g., about 5 slm, about 6, slm, about 7 sim, about 8 slm, about 9 sim, about 10 slm, about 11 slm, about 12 slm, about 13 slm, about 14 slm, about 15 slm, about 16 slm, about 17 slm, about 18 slm, about 19 slm, about 20 slm, about 21 sim, about 22 slm, about 23 slm, about 24 slm, about 25 sim, about 26 slm, about 27 slm, about 28 slm, about 29 slm, about 30 slm, about 31 sim, about 32 sim, about 33 slm, about 34 slm, about 35 slm, about 36 slm, about 37 slm, about 38 slm, about 39 slm, about 40 slm or the like.

The second gas may be introduced from the plurality of second nozzles 501 towards the substrate at a gas velocity of about 1 m/s to about 20 m/s, e.g., about 1 m/s, about 2 m/s, about 3 m/s, about 4 m/s, about 5 m/s, about 6 m/s, about 7 m/s, about 8 m/s, about 9 m/s, about 10 m/s, about 11 m/s, about 12 m/s, about 13 m/s, about 14 m/s, about 15 m/s, about 16 m/s, about 17 m/s, about 18 m/s, about 19 m/s, about 20 m/s, or the like.

The method 600 includes introducing the first gas radicals and the second gas while rotating the substrate support on the rotatable cylinder, described above. The method 600 includes introducing the first gas radicals and the second gas while the pressure of the processing chamber is about 0.1 Torr to about 20 Torr. For example, introducing the first gas radicals and the second gas may occur while the pressure of the processing chamber is at a reduced pressure of about 1 Torr to about 5 Torr, e.g., about 1 Torr, about 2 Torr, about 3 Torr, about 4 Torr, about 5 Torr, or the like.

At operation 605, method 600 includes producing an oxidation radical (e.g., hydroxyl radical) as a function of the first gas radical and the second gas. Producing an oxidation radical may include producing a hydroxyl radical as a function of a reaction between the first gas radical and the second gas. For example, the hydroxyl radical may be formed as a function of reacting a first gas oxygen radical with a second gas of hydrogen. The reaction of the first gas radical and the second gas may result in about 5% to about 20% of products being hydroxyl radical, e.g., about 5%, about 6%, about 7%, about 8%, about 9%, about 10%, about 11%, about 12%, about 13%, about 14%, about 15%, about 16%, about 17%, about 18%, about 19%, about 20%, or the like. A reaction of the first gas radical and the second gas produces a hydroxide radical in processing chamber when hydrogen gas is more than 50 mol % or vol % present in a H₂:radical-O₂ mixture. For example, a hydroxide radical may be formed when hydrogen gas of a H₂:radical-O₂ mixture is between 50 mol % or vol % and 80 mol % or vol %. Without being bound by theory hydroxyl radicals can help carry away nitrogen during oxidation of silia nitride, e.g., via the removal of NH₃ that is formed by the reaction of hydrogen with nitrogen. This can produce a better quality silica oxide, SiO₂, with less nitrogen content in the remaining film.

The oxidation radical (e.g., hydroxyl radical) then oxidizes a surface layer 701 of a memory hole of the substrate. Oxidizing the surface layer 701 includes oxidizing a silicon nitride layer to a silicon oxide layer, as shown in FIGS. 7A-7C. Without being bound by theory, the oxidation of the silicon nitride layer to the silicon oxide layer can include reacting a hydrogen radical with the nitrogen of the silicon nitride layer to form ammonia, NH₃, which is then released via a gas. The oxidation radical includes a hydroxyl radical 702, in which the hydroxyl radical flows into a memory hole 703 of the substrate, as shown in FIG. 7A. The hydroxyl radical 702 flows into the memory hole 703 to provide improved conformality, as shown in FIG. 7B. For example, the hydroxyl radical may flow into the memory hole to provide greater than 80% conformality, e.g., about 80%, about 85%, about 90%, about 95%, or about 100% conformality. The hydroxyl radical 702 reacts with the silicon nitride outer layer 701, oxidizing the outer layer 701 to silicon oxide, as shown in FIG. 7C.

The present system described herein provides the benefit of mixing plasma and molecular species that surpass the use of just one gas stream by itself. A second gas source that injects a molecular gas into the processing chamber separately from a first radical gas allows for the control of new species production with improved chemistry. Additionally, the two separate gas sources mixed in the internal volume to allow for the creation of a new species that provides enhanced conformality when processing a substrate in the processing chamber. Without being bound by theory these new species can have short lifetimes. Mixing in the chamber over the substrate is advantageous compared to generating species remotely, as remotely-produced species may recombine during delivery to the processing region.

A reduction in remote plasma source damage is also achieved using the substrate processing system described herein. Hydrogen ions, H+, cause damage to dielectric liners of the remote plasma source and/or the conduit extending between the remote plasma source and the processing chamber. As such, the second gas source prevents this damage and improves the lifespan of the dielectric liner of the remote plasma source. The gas flow of the first gas source and the second gas source may be independently controlled to maintain plasma parameters within the processing volume within a plasma window, while still having high total chamber flows to improve process performance.

While the foregoing is directed to embodiments of the disclosure, other and further embodiments may be devised without departing from the basic scope thereof, and the scope thereof is determined by the claims that follow.

What is claimed is:

1. A substrate processing system, comprising:
a processing chamber;
a gas inlet conduit coupled to a first nozzle of the processing chamber;
a remote plasma source fluidly coupled to the gas inlet conduit, wherein the remote plasma source is fluidly coupled to a first gas source; and
a second gas source fluidly coupled to a plurality of second nozzles of the processing chamber, wherein the first nozzle is oriented on a first side of the processing chamber and the plurality of the second nozzles are oriented on a second side of the processing chamber; and
a controller configured to:
form a plasma of a plasma gas using the remote plasma source;
produce a first gas radical by flowing the first gas through the remote plasma source;
introduce the first gas radical into the processing chamber using the first nozzle;
introduce a second gas using the plurality of second nozzles fluidly coupled to the second gas source; and
produce an oxidation radical by mixing the first gas radical and the second gas in the processing chamber.

2. The system of claim 1, wherein the first gas is a reactive gas mixture comprising Ar, H₂ or O₂, or a combination thereof.

3. The system of claim 2, wherein the first gas is O₂.

4. The system of claim 2, wherein the second gas is a reactive gas comprising H₂ or O₂, and wherein the second gas is different from the first gas.

5. The system of claim 4, wherein the second gas is H₂.

6. The system of claim 1, wherein the plurality of second nozzles comprises about 2 nozzles to about 15 nozzles.

7. The system of claim 1, wherein the oxidation radical is a hydroxyl radical.

8. The system of claim 1, wherein the processing chamber comprises a pressure of about 0.1 Torr to about 20 Torr.

9. The system of claim 8, wherein the processing chamber comprises a pressure of about 1 Torr to about 5 Torr.

10. A method of producing hydroxyl radicals, comprising;
forming, via a controller, a plasma of a plasma gas using a remote plasma source fluidly coupled to a gas inlet conduit coupled to a first nozzle of a processing chamber;
producing, via the controller, a first gas radical by flowing a first gas from a first gas source through the remote plasma source;
introducing, via the controller, the first gas radical into the processing chamber using the gas inlet conduit coupled to the first nozzle;
introducing, via the controller, a second gas from a second gas source using a plurality of second nozzles fluidly of the processing chamber, wherein the first nozzle is oriented on a first side of the processing chamber and the plurality of second nozzles are oriented on a second side of the processing chamber; and
producing, via the controller, an oxidation radical by mixing the first gas radical and the second gas in the processing chamber.

11. The method of claim 10, wherein the first gas is a reactive gas mixture comprising Ar, H₂ or O₂, or a combination thereof.

12. The method of claim 11, wherein the first gas is O₂.

13. The method of claim 10, wherein the second gas is a reactive gas comprising H₂ or O₂, and wherein the second gas is different from the first gas.

14. The method of claim 13, wherein the second gas is H₂.

15. The method of claim 10, wherein the plurality of second nozzles comprises about 2 nozzles to about 15 nozzles.

16. The method of claim 10, wherein the oxidation radical is a hydroxyl radical.

17. The method of claim 10, wherein the processing chamber comprises a pressure of about 0.1 Torr to about 20 Torr.

18. The method of claim 17, wherein the processing chamber comprises a pressure of about 1 Torr to about 5 Torr.

19. The method of claim 10, further comprising oxidizing an outer layer of a substrate disposed in the processing chamber.

20. A computer readable medium configured to:
form, via a controller, a plasma of a plasma gas using a remote plasma source fluidly coupled to a gas inlet conduit coupled to a first nozzle of a processing chamber;
produce, via the controller, a first gas radical by flowing a first gas from a first gas source through the remote plasma source;
introduce, via the controller, the first gas radical into the processing chamber using the gas inlet conduit coupled to the first nozzle;
introduce, via the controller, a second gas from a second gas source using a plurality of second nozzles fluidly of the processing chamber, wherein the first nozzle is oriented on a first side of the processing chamber and the plurality of second nozzles are oriented on a second side of the processing chamber; and
produce, via the controller, an oxidation radical by mixing the first gas radical and the second gas in the processing chamber.
